(19) United States
(12) Patent Application Publication
(10) Pub. No.: US 2003/0140845 A1
(43) Pub. Date: Jul. 31, 2003

(54) Pressure vessel

(75) Inventors: Mark Philip D'Evelyn, Niskayuna, NY (US); Kristi Jean Narang, Voorheesville, NY (US); Robert Arthur Giddings, Slingerlands, NY (US); Robert Vincent Leonelli JR., Westerville, OH (US); Stephen Lee Dole, Columbus, OH (US)

Correspondence Address: GENERAL ELECTRIC COMPANY, GLOBAL RESEARCH CENTER, PATENT DOCKET RM. 4A59, PO BOX 8, BLDG. K-1 ROSS, NISKAYUNA, NY, 12309, US

(73) Assignee: General Electric Company, Niskayuna, NY (US)

(21) Appl. No.: 09/683,658

(22) Filed: Jan. 31, 2002

(51) Int. Cl. C30B 1/00; C30B 3/00; C30B 5/00; C30B 28/02; C30B 7/00; C30B 21/02; C30B 28/06

(52) U.S. Cl. 117/8

(57) ABSTRACT

A pressure vessel for processing at least one material in a supercritical fluid. The pressure vessel includes a self-pressurizing capsule for containing at least one material and the supercritical fluid in a substantially air-free environment, a pressure transmission medium surrounding the capsule for maintaining an outer pressure on the capsule, at least one heating element insertable in the pressure transmission medium such that the heating element surrounds the capsule, a temperature measurement means for measuring a temperature of the capsule, a temperature controller for controlling the temperature and providing power to the heating element, a restraint to contain and hold in place the capsule, the pressure transmission medium, and the heating element, and at least one seal between the restraint and the pressure transmission medium for preventing escape of the pressure transmission medium. Methods of using the pressure vessel, processing a material at high temperature and high pressure in the presence of a supercritical fluid within the capsule are also described.

### BACKGROUND OF INVENTION

The invention relates generally to pressure vessels. More particularly, the present invention relates to an improved pressure vessel for processing at least one material in a supercritical fluid.

Many chemical or material synthesis processes can best be run at elevated pressures and temperatures within a vessel or cell containing either a solid, liquid, or gaseous medium. Well-known cell designs, such as those employed in commercial synthetic diamond manufacturing, can be used when the medium is a solid at room temperature. When the medium is a liquid or a gas at room temperature, reactions can be carried out at pressures of up to a few kilobar (kbar) in autoclaves. No suitable autoclave design is currently available, however, for processing in a medium other than an inert gas and at pressures exceeding more than a few kilobar.

In instances where even higher pressures are needed, reactants and solvent are sealed within a capsule and then subjected to an external pressure supplied by a press, such as a piston cylinder press, a belt-type uniaxial press, or a multi-anvil press. If the externally applied pressure is insufficient, the capsule will burst. Conversely, if the external pressure is too great, the capsule will be crushed. In both instances, reactant and solvent are released from the capsule and infiltrate into the pressurized cell or vessel.

Present methods of processing materials under high pressure, high temperature conditions generally employ capsules that are filled with reactants and solvents and subsequently sealed. The filling operation is usually carried out under ambient conditions, as generally applicable methods for excluding air from the capsule are not available. Consequently, the process may be subject to contamination by air introduced into the capsule during the filling process.

Materials cannot be processed under high pressure, high temperature conditions in a substantially air-free environment. Therefore, what is needed is an improved pressure vessel in which materials can be processed under high pressure, high temperature conditions. More particularly, what is needed is a pressure vessel in which materials can be processed with a liquid, gas, or supercritical fluid where the process pressure exceeds a few kilobar. What is also needed is a pressure vessel in which materials can be processed in an air-free environment under high pressure, high temperature conditions.

### SUMMARY OF INVENTION

The present invention meets these and other needs by providing a pressure vessel for reacting at least one material with a supercritical fluid in a substantially air-free environment under high pressure, high temperature conditions. The apparatus also includes a self-pressurizing vessel in which the reaction takes place and is relatively insensitive to the actual process pressure. The present invention also includes methods of using the pressure vessel and processing a material at high temperature and high pressure in the presence of a supercritical fluid within the pressure vessel.

Accordingly, one aspect of the invention is to provide a pressure vessel for processing at least one material in a supercritical fluid. The pressure vessel a capsule for containing the at least one material and the supercritical fluid in a substantially air-free environment, the capsule being self-pressurizing; a pressure transmission medium for maintaining an outer pressure on the capsule, the pressure transmission medium surrounding the capsule; a heating system for heating the capsule, the heating system comprising at least one heating element that is insertable in the pressure transmission medium such that the at least one heating element is proximate to the capsule and a wattage control system electrically coupled to the at least one heating element, wherein the wattage control system provides power to the at least one heating element; a restraint to contain and hold the capsule, pressure transmission medium, and the at least one heating element in place, wherein the restraint maintains the capsule, pressure transmission medium, and the at least one heating element at a constant pressure; and at least one seal for preventing escape of the pressure transmission medium, the at least one seal being disposed between the restraint and the pressure transmission medium.

A second aspect of the invention is to provide a capsule for containing at least one material and a supercritical fluid in a substantially air-free environment. The capsule has at least one wall, a closed end, and a sealed end defining a chamber therein for containing the at least one material and supercritical fluid, wherein the capsule is self-pressurizing.

A third aspect of the invention is to provide a pressure vessel for processing at least one material in a supercritical fluid. The pressure vessel comprises: a capsule for containing the at least one material and supercritical fluid in a substantially air-free environment, wherein the capsule has at least one wall, a closed end, and a sealed end defining a chamber therein for containing the at least one material and supercritical fluid, and wherein the capsule is self-pressurizing; a pressure transmission medium for maintaining an outer pressure on the capsule, the pressure transmission medium surrounding the capsule; a heating system for heating the capsule, the heating system comprising at least one heating element insertable in the pressure transmission medium such that the at least one heating element is proximate to the capsule, at least one temperature sensor disposed proximate to the capsule for measuring a temperature of said capsule, a wattage control system electrically connected to the at least one heating element and the at least one temperature sensor, wherein the wattage control system provides power to the at least one heating element and controls the temperature; a restraint to contain and hold in place the capsule, pressure transmission medium, and the at least one heating element, wherein the restraint maintains the capsule, pressure transmission medium, and the at least one heating element at a constant pressure; and at least one seal for preventing escape of the pressure transmission medium, the at least one seal being disposed between the restraint and the pressure transmission medium.

A fourth aspect of the invention is to provide a method of using a pressure vessel to process at least one material at high temperature and high pressure in the presence of a supercritical fluid. The method comprises the steps of: providing a sealed capsule containing the at least one material and a solvent that forms the supercritical fluid, wherein the capsule is self-pressurizing; providing a pressure vessel comprising a restraint for containing the sealed capsule, a pressure transmission medium disposed within the pressure vessel, and at least one heating element disposed within the pressure transmission medium and electrically coupled to a wattage control system; disposing the sealed capsule within the pressure transmission medium such that the sealed capsule is proximate to the at least one heating element; placing the pressure vessel containing the pressure transmission medium, the sealed capsule, and the at least one heating element in a press; pressurizing the press to apply a predetermined pressure to the pressure vessel, the pressure transmission medium, the sealed capsule, and the at least one heating element; and providing electrical power from the wattage control system to the at least one heating element, thereby heating the sealed capsule to a predetermined temperature, wherein the solvent contained within the sealed capsule becomes a supercritical fluid and wherein the supercritical fluid generates a predetermined pressure within the sealed capsule; and counterbalancing the predetermined pressure within the sealed capsule by maintaining an equivalent pressure by the restraint and transmitting the equivalent pressure through the pressure transmission medium, wherein the at least one material is processed at high temperature and high pressure in the presence of a supercritical fluid.

A fifth aspect of the invention is to provide a method of processing at least one material at high temperature and high pressure in the presence of a supercritical fluid. The method comprises the steps of: providing a sealed capsule containing the at least one material and a solvent that forms a supercritical fluid, wherein the capsule is self-pressurizing; providing a pressure vessel comprising a restraint, a pressure transmission medium disposed within the restraint, and at least one heating element disposed within the restraint; disposing the sealed capsule within the pressure transmission medium such that the sealed capsule is proximate to the at least one heating element; heating the sealed capsule to a predetermined temperature by providing electrical power to the at least one heating element, wherein the solvent contained within the sealed capsule becomes a supercritical fluid, wherein the supercritical fluid generates a predetermined pressure within the sealed capsule; and counterbalancing the predetermined pressure within the sealed capsule by maintaining an equivalent pressure by the restraint and transmitting the equivalent pressure through the pressure transmission medium, wherein the at least one material reacts with the supercritical fluid within the sealed capsule at high pressure and high temperature.

A sixth aspect of the invention is to provide a metal nitride single crystal. The metal nitride single crystal is formed by: enclosing a metal nitride source material and a solvent within a sealed capsule that is self-pressurizing; disposing the sealed capsule within a pressure vessel comprising a restraint, a pressure transmission medium disposed within the restraint, and at least one heating element disposed within the restraint; heating the sealed capsule to a predetermined temperature, wherein the solvent contained within the sealed capsule becomes a supercritical fluid and generates a predetermined pressure within the sealed capsule; and counterbalancing the predetermined pressure within the sealed capsule by applying a pressure provided by the restraint to the sealed capsule.

These and other aspects, advantages, and salient features of the present invention will become apparent from the following detailed description, the accompanying drawings, and the appended claims.

### BRIEF DESCRIPTION OF DRAWINGS

FIG. 1 is a schematic representation of a pressure vessel assemply of the present invention in which the restraint comprises a hydraulic press with a pair of punches and a die;

FIG. 2 is a schematic representation of a capsule in accordance with one embodiment of the instant invention;

FIG. 3 is a schematic representation of a pressure vessel of the present invention in which the restraint comprises a multi-anvil press;

and FIG. 4 is a schematic representation of a pressure vessel of the present invention in which the restraint comprises a die and reinforced end flanges.

### DETAILED DESCRIPTION

In the following description, like reference characters designate like or corresponding parts throughout the several views shown in the figures. It is also understood that terms such as “top,” “bottom,” “outward,” “inward,” and the like are words of convenience and are not to be construed as limiting terms.

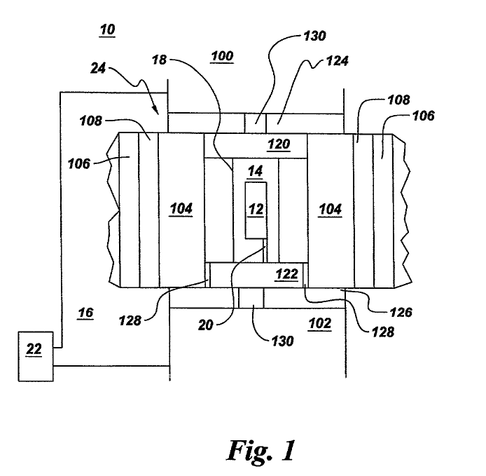

Referring to the drawings in general and to FIG. 1 in particular, it will be understood that the illustrations are for the purpose of describing a preferred embodiment of the invention and are not intended to limit the invention thereto. Pressure vessel tooling (also referred to herein as “pressure vessel”) 10 for processing at least one material in a supercritical fluid is shown in FIG. 1. Pressure vessel 10 comprises a cell. A sealed, self-pressurizing capsule 12 for containing the at least one material and a solvent is disposed within the cell. The solvent becomes a supercritical fluid at high temperature and high pressure (also referred to herein as “HPHT”). HPHT conditions encompass temperatures greater than about 100° C. and pressures greater than about 1 atm. A pressure transmission medium 14 disposed in the cell surrounds the self-pressurizing capsule 12 and maintains an outer pressure on the self-pressurizing capsule 12 to prevent the self-pressurizing capsule 12 from rupturing or bursting. The high pressure necessary for processing the at least one material is generated within the self-pressurizing capsule 12 itself, rather than the necessary pressure being externally applied to the capsule. As the capsule is heated, the vapor pressure of the solvent increases. The vapor pressure of the solvent at a given temperature and quantity of solvent present (also known as “percent fill”) within the capsule can be determined from the phase diagram of the solvent. At a sufficiently high temperature and pressure, the solvent becomes a supercritical fluid. As the internal pressure within the self-pressurizing capsule 12 increases, the walls of the self-pressurizing capsule 12 deform outward and press against pressure transmission medium 14.

Pressure transmission medium 14 is thermally stable up to the temperature at which the at least one material is to be processed in a supercritical fluid. That is, pressure transmission medium 14 does not decompose or react with the other components of pressure vessel 10, or undergo a solid state phase transition. Pressure transmission medium 14 preferably remains a solid at the processing temperature and has a relatively low shear strength and internal friction. For example, the internal friction is below about 0.2. It is desirable that the pressure transmission medium 14, when placed in the cell of pressure vessel 10, be compacted to greater than about 85% of its theoretical density in order to avoid introducing excess porosity into the cell. Pressure transmission medium 14 is preferably a solid up to about 1000° C. and, more preferably, up to about 1300° C. In one embodiment, pressure transmission medium 14 comprises at least one alkali halide, such as NaCl, NaBr, or NaF. Sodium chloride performs particularly well at temperatures approaching its melting point, which, at pressures of about 10 to about 20 kbar, is between about 1000° C. and about 1150° C. Alternatively, pressure transmission medium 14 may comprise at least one of talc, pyrophyllite, molybdenum disulfide, graphite, hexagonal boron nitride, silver chloride, calcium fluoride, strontium fluoride, calcium carbonate, magnesium oxide, zirconium oxide, merylinite clay, bentonite clays, and sodium silicate.

At least one heating element 18 is disposed within the cell and proximate to the self-pressurizing capsule 12. The at least one heating element 18 comprises at least one of graphite, nichrome, niobium, titanium, tantalum, stainless steel, nickel, chromium, zirconium, molybdenum, tungsten, rhenium, hafnium, platinum, silicon carbide, and combinations thereof. The at least one heating element 18 may take the form of at least one resistively heated tube, foil, ribbon, bar, wire, or combinations thereof.

A wattage control system 16 is electrically connected to the at least one heating element 18 to provide power for heating the self-pressurizing capsule 12. Additionally, wattage control system 16 may either directly or indirectly control the temperature of the self-pressurizing capsule 12. In one embodiment, the wattage control system 16 includes a controller 22 for powering and controlling the at least one heating element 18. Controller 22 preferably provides closed-loop control of the heating power. In one embodiment, the wattage control system 16 includes at least one temperature sensor 20 for generating temperature signals associated with the self-pressurizing capsule 12. In another embodiment, the power controller provides closed-loop temperature control in response to the temperature signals generated from the temperature sensor 20. In one embodiment, the at least one temperature sensor 20 is situated proximate to, and, preferably, in direct contact with the self-pressurizing capsule. Temperature sensor 20 may include at least one of a thermocouple, thermistor, an optical fiber coupled to an optical pyrometer, or any combination thereof.

For some types of supercritical fluid processing at high pressure and high temperature, an isothermal cell is desired. In other applications, however, a temperature gradient between two ends of the self-pressurizing capsule 12 is desired. For example, crystal growth is among those applications in which a temperature gradient is sometimes desirable. In one embodiment, the temperature gradient may be achieved by placing the self-pressurizing capsule 12 closer to one end of the cell than the other. Alternatively, the temperature gradient is produced by providing at least one heating element 18 having a non-uniform resistivity along its length. Non-uniform resistivity of the at least one heating element 18 may be provided, for example, by providing at least one heating element 18 having a non-uniform thickness, by perforating the at least one heating element 18 at selected points, or by providing at least one heating element 18 that comprises a laminate of at least two materials of differing resistivity at selected points along the length of the at least one heating element 18. In one embodiment, at least two independent temperature sensors are provided to measure and control the temperature gradient between the opposite ends of the self-pressurizing capsule 12. In one embodiment, closed-loop temperature control is provided for at least two locations within the cell. The at least one heating element 18 may also comprise multiple zones which may be individually powered to achieve the desired temperature gradient between two ends of the self-pressurizing capsule 12.

A restraint 24 is positioned so as to apply a compensating pressure to the external surface of the pressure transmission medium 14 to contain and hold in place (i.e., maintain the relative positions) and prevent shifting of the self-pressurizing capsule 12, the pressure transmission medium 14, the at least one heating element 18, and, additionally, the temperature sensor 20, with respect to each other during processing. Restraint 24 also serves to prevent bursting of the self-pressurizing capsule 12 by counterbalancing the pressure generated within the self-pressurizing capsule 12 at high temperature. The individual component parts, namely the pressure transmission medium 14 and the capsule 12, are maintained in position relative to each other during the process by restraint 24. Restraint 24 exerts an external pressure on self-pressurizing capsule 12 of less than about than about 1 kbar at ambient temperature.

The self-pressurizing capsule 12 is self-pressurizable up to between about 1 atm (≈1 bar) and about 80 kbar. In one embodiment, self-pressurizing capsule 12 is pressurizable up to between about 5 kbar and about 80 kilobar. In another embodiment, self-pressurizing capsule 12 is pressurizable up to between about 5 kbar and about 60 kilobar. The self-pressurizing capsule 12 is typically formed from a malleable metal such as, but not limited to, copper, silver, gold, platinum, stainless steel or the like. Additionally, self-pressurizing capsule 12 typically has low hydrogen permeability and is chemically inert with respect to the supercritical fluid and the material to be processed within the self-pressurizing capsule 12.

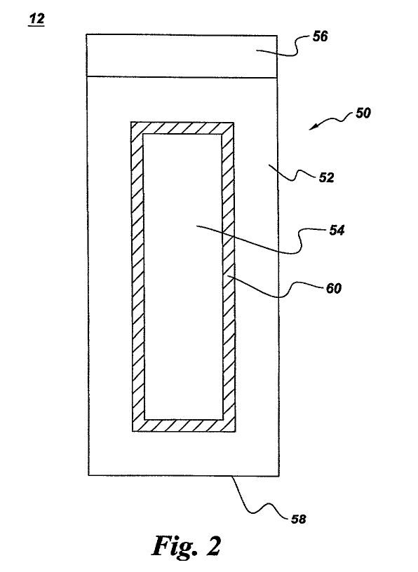

In one embodiment of the invention, self-pressurizing capsule 12 comprises an annular housing 50 having a wall 52 defining an inner cavity or chamber 54, a closed end 58 and a sealed end 56, as shown in FIG. 2. Typically, outer wall 52, closed end 58 and sealed end 56 each have a thickness in the range between about 0.5 mm to about 25 mm. Sealed end 56 is formed after introducing at least one material to be processed under HPHT conditions and the solvent into inner chamber 54. Sealed end 56 is formed while maintaining inner chamber 54 under vacuum or under an atmosphere comprising either solvent vapor, an inert gas, or combinations thereof. Self-pressurizing capsule 12 may also include a baffle (not shown) to divide inner chamber 54 into more than one section, in fluid communication with each other through through-holes located in the baffle. Thus, inner chamber 54, once sealed, provides an air-free environment for processing the at least one material in the presence of a supercritical fluid under HPHT conditions. Consequently, the at least material can be processed with a reduced risk of contamination.

In another embodiment, the self-pressurizing capsule 12 includes an inert liner 60, which is slidingly inserted into inner cavity 54 prior to introducing the at least one material and solvent into the self-pressurizing capsule 12. Inert liner 60 serves as an additional barrier to prevent or minimize chemical attack of the self-pressurizing capsule by the at least one material, solvent, or supercritical fluid. Inert liner 60 typically has a thickness of between about 1 micron and about 5 mm. Inert liner 60 is formed from a material that is different from that of the self-pressurizing capsule 12 and comprises at least one of gold, platinum, rhodium, palladium, silver, iridium, ruthenium, silica, and combinations thereof.

The self-pressurizing capsule and methods of filling and sealing the self-pressurizing capsule are described in more detail in U.S. patent application Ser. No. ______, filed on ______, 2001, by Mark Philip D'Evelyn, et al., entitled “High Temperature High Pressure Capsule for Processing Materials in Supercritical Fluids,” which is incorporated herein by reference in its entirety.

As presented above, restraint 24 (FIG. 1) is positioned so as to apply a counterbalancing or compensating pressure to the external surface of the pressure transmission medium 14 in order to contain and hold in place the self-pressurizing capsule 12 and pressure transmission medium 14. Restraint 24 can include any number of combined devices such as, but not limited to, hydraulic presses, plates, clamps, belts, dies, punches, anvils, pistons, or the like.

In one embodiment, restraint 24 includes a uniaxial hydraulic press (not shown), a pair of opposing punches (for example, top punch 100 and bottom punch 102), a die 104, and at least one compression ring 106. Preferably, top punch 100 and bottom punch 102 are flat-bottomed punches. Anvils may be substituted for the opposing punches. The at least one compression ring 106 is typically fabricated from hardened steel and serves to compress die 104 and permit greater internal pressures to be generated within self-pressurizing capsule 12 without failure of the die 104. A cooling sleeve 108 may be optionally positioned between the die 104 and the at least one compression ring 106 to provide efficient cooling of the die 104. The cooling sleeve 108 may contain at least one cooling channel through which a cooling medium is circulated. The cooling medium may be either a gas, such as argon, helium, nitrogen, or the like, or a liquid, such as, but not limited to, water, brine, mixtures of water and ethylene glycol, and the like. In operation, die 104 is surrounded by at least one compression ring 106 and placed on bottom punch 102. Instead of—or in addition to—being surrounded by compression ring 106, die 104 may be contained within at least one tension-wound steel wire, at least one steel ribbon, and combinations thereof. Die 104 is typically a straight-wall die that may be fabricated from a variety of materials including, but not limited to, cemented tungsten carbide and hardened steel. Alternatively, die 104 may have either an angled wall or a concave wall, with the center portion of the die 104 having a smaller inner diameter than the inner diameter near the ends of the die 104. Pressure transmission medium 14, which is typically sodium chloride (NaCl), is placed within die 104. In order to minimize chemical reactivity and friction between pressure transmission medium 14 and die 104, at least one liner or lubricant may be positioned between pressure transmission medium 14 and die 104. Suitable liner or lubricant materials include, but are not limited to, lead foil, gold, silver, copper, talc, pyrophyllite, molybdenum disulfide, graphite, hexagonal boron nitride, silver chloride, calcium carbonate, magnesium oxide, zirconium oxide, merylinite clays, bentonite clays, and sodium silicate. The at least one heating element 18 and at least one temperature sensor 20 are next inserted in the pressure transmission medium 14. Self-pressurizing capsule 12, containing at least one reactant and a solvent that becomes a supercritical fluid at high temperature and high pressure, is inserted into pressure transmission medium 14. Finally, top punch 102 is placed on top of the die to close the pressure vessel tooling 10.

Once assembled, the pressure vessel tooling 10 is moved into a uniaxial hydraulic press, where pressure is applied onto opposing top and bottom punches 100, 102. The press can be loaded initially to full force. Alternatively, force can be applied to a predetermined level, or to obtain a selected stroke in order to densify the components, such as the pressure transmission medium 14, top gasket 124, and bottom gasket 126, and to seal pressure vessel 10. Additional force is then applied as the self-pressurizing capsule 12 is heated, in order to keep the press from stroking (i.e., changing the displaced position of top and bottom punches 100 and 102), thus maintaining top and bottom punches 100 and 102 in a fixed or constant position. At lower temperatures, only a modest internal pressure (for example, less than about 1 kbar) is present within the self-pressurizing capsule 12, and virtually the entire punch load is imposed onto the die 104. The self-pressurizing capsule 12 is heated, for example, by passing electrical current between top and bottom punches 100 and 102 and through heating element 18. As the self-pressurizing capsule 12 is heated, the solvent initially vaporizes and, with increasing temperature, becomes a supercritical fluid. The internal pressure correspondingly builds up within the self-pressurizing capsule 12. The actual amount of internal pressure generated within self-pressurizing capsule 12 at a given temperature can be determined by the phase diagram of the solvent that is selected for processing the at least one material. The self-pressurizing capsule 12 deforms outward, loading the pressure transmission medium 14 and, in turn, exerting pressure against the underside of top punch 100 and the top of bottom punch 102. As the internal pressure within the capsule and pressure transmission medium increases, an increasing fraction of the punch load counterbalances or compensates for the internal pressure. However, a significant fraction (i.e., at least about 30%) of the punch load remains on the die 104 so as to reduce longitudinal or axial stresses in die 104.

The performance of an HPHT apparatus may be characterized by its pressure response, which is defined as the percent increase in cell pressure divided by the percent increase in press force that produces the increased cell pressure, relative to a reference operating condition. In conventional HPHT devices, the pressure response is typically high, ranging from near unity for piston cylinder presses to about 50% for belt-type presses and multi-anvil presses. Under such circumstances, precise control of the pressure applied to the capsule via the press force is required in order to prevent the capsule from either bursting or being crushed.

In contrast to conventional HPHT devices, the pressure vessel tooling 10 of the present invention is a “zero stroke” apparatus, in which the pressure response is below 0.2, and, more preferably below, 0.05. A zero stroke apparatus is much easier to control in supercritical-fluid-processing applications, and is able to capture or contain the pressure generated within the capsule with little or no tendency to crush it. Although some stroking (e.g., an increase or decrease in the separation between the punches or anvils) may occur during operation, the extent of stroking is much smaller than in previous designs.

Because of the geometry of the pressure vessel tooling 10 of the present invention, an increase in load on the punches is almost completely borne by the die 104, and the increase in cell pressure is very small. The resulting pressure response value of pressure vessel tooling 10 is below 0.2 and, most likely below 0.05, during operation.

In one embodiment, a top seal 120 and bottom seal 122 are interposed between the top and bottom punches 100, 102, respectively, and the pressure transmission medium 14 to prevent escape of the pressure transmission medium 14. Top and bottom seals 120, 122 typically comprise steel end caps, which are optionally fitted with a ring fabricated from brass or another similarly deformable material. At least one of top and bottom seals 120, 122 is separated from contact with die 104 by a bushing 128 to prevent creation of an electrical short between the die 104 and either the at least one heating element 18 or the electrical leads connecting the at least one heating element 18 to the wattage source. The insulating bushing preferably has an internal friction between about 0.2 and about 0.7 under operating conditions, or, more preferably, between about 0.25 and about 0.5. The insulating bushing comprises at least one of pyrophyllite, talc, olivine, magnesium oxide, calcium carbonate, calcium oxide, strontium oxide, barium oxide, textilite and similar glued paper composites, merylinite clay, bentonite clay, sodium silicate, and hexagonal boron nitride.

Top gasket 124 and bottom gasket 126 are typically disposed between top punch 100 and die 104 and bottom punch 102 and die 104, respectively. Alternatively, top gasket 124 and bottom gasket 126 may also be disposed between top punch 100 and top seal 120 and bottom punch 102 and bottom seal 122, respectively. At least one of top gasket 124 and bottom gasket 126 is an electrical insulator, so that die 104 does not act as an electrical short for the at least one heating element 18. In one embodiment, the insulating gasket comprises at least one of natural or synthetic rubber, Mylar® (polyester film), polyimide, Teflon® (fluorocarbon polymer, tetrafluoroethylene fluorocarbons, fluorinated ethylene-propylene, and the like), pyrophyllite, talc, olivine, magnesium oxide, calcium carbonate, calcium oxide, strontium oxide, barium oxide, textilite and similar glued paper composites, merylinite clay, bentonite clay, sodium silicate, and hexagonal boron nitride. In one embodiment, a non-insulating, or electrically conductive, gasket comprises at least one of copper, brass, molybdenum, graphite, nickel, cobalt, iron, and stainless steel. In one embodiment in which top gasket 124 is disposed between top punch 100 and top seal 120 and bottom gasket 126 is disposed between bottom punch 102 and bottom seal 122, top gasket 124 and bottom gasket 126 are formed with a conductive element 130 within an insulating gasket element so that electrical current may pass from punch 100 to heating element 18 without die 104 acting as an electrical short. The conductive element may comprise at least one of molybdenum, graphite, tungsten, tantalum, niobium, copper, copper alloy, nickel, nickel alloy, iron, iron alloy, and the insulating gasket element comprises at least one of natural rubber, synthetic rubber, Mylar® (polyester film), polyimide, Teflon® (fluorocarbon polymer, tetrafluoroethylene fluorocarbons, fluorinated ethylene-propylene, and the like), pyrophyllite, talc, olivine, magnesium oxide, calcium carbonate, calcium oxide, strontium oxide, barium oxide, textilite and similar glued paper composites, merylinite clay, bentonite clay, sodium silicate, and hexagonal boron nitride. In one embodiment, top gasket 124 and bottom gasket 126 may also act as the seal to prevent escape of pressure transmission medium 14.

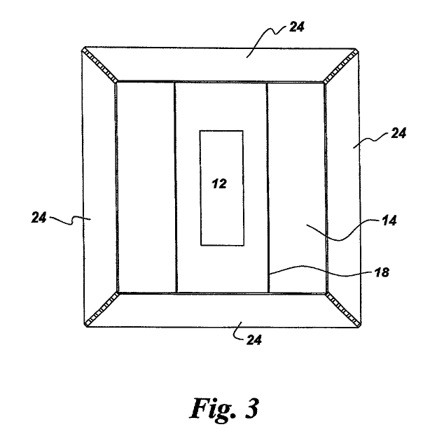

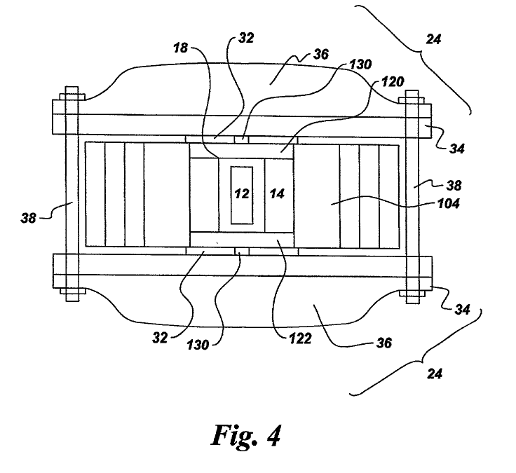

In another embodiment of the invention, shown in FIG. 3, the restraint 24 comprises a multi-anvil press having at least four anvils. In this embodiment, the self-pressurizing capsule 12, pressure transmission medium 14, and at least one heating element 18 are configured in a fashion similar to that shown in FIG. 1, but are instead inserted into a multi-anvil press having at least four anvils. The pressure transmission medium 14 is surrounded by support plates, which support the load exerted by the press when the capsule is at low temperature and low internal pressure. The support plates are separated from one another by gasket material, which is preferably electrically insulating. The gasket material comprises at least one of natural or synthetic rubber, Mylar® (polyester film), polyimide, Teflon® (fluorocarbon polymer, tetrafluoroethylene fluorocarbons, fluorinated ethylene-propylene, and the like), pyrophyllite, talc, olivine, magnesium oxide, calcium carbonate, calcium oxide, strontium oxide, barium oxide, textilite and similar glued paper composites, merylinite clay, bentonite clay, sodium silicate, and hexagonal boron nitride. External pressure may be applied to the support plates either by four or more independent anvils or pistons or by a multi-anvil assembly placed inside a uniaxial press, a split-sphere press, or other similar pressurizing apparatus known in the art. As the capsule is heated, internal pressure builds up within the self-pressurizing capsule 12, causing its walls to deform outward against the pressure transmission medium 14. As the pressure in the pressure transmission medium 14 builds up, an increasing fraction of the press force counterbalances—or compensates for—the internal pressure, and a decreasing fraction of the press force is supported by the support plates. Instead of producing a substantial increase in cell pressure, an increase in press force is largely borne by the support plates and the pressure response value is below 0.2.

In yet another embodiment, shown in FIG. 4, restraint 24 comprises a die and reinforced end flanges. The self-pressurizing capsule 12, pressure transmission medium 14, heater 18, top seal 120, bottom seal 122, and die 104 are surrounded by at least one restraint 24 and are configured in a fashion similar to that shown in FIG. 1, but are instead enclosed by two end flanges 34, each of which is reinforced by an I-beam 36 or similar structural support. The die 104 is separated from the end flanges 34 by gaskets 32. In one embodiment, gaskets 32 contact the upper and surfaces of die 104 so as to contain and prevent leakage of pressure transmission medium 14 from die 104. At least one gasket 32 contains an electrically insulating portion to prevent creation of an electrical short between the die 104 and either the at least one heating element 18 or the electrical leads connecting heating element 18 to the wattage source. The insulating gasket material may comprise at least one of natural or synthetic rubber, Mylar® (polyester film), polyimide, Teflon® (fluorocarbon polymer, tetrafluoroethylene fluorocarbons, fluorinated ethylene-propylene, and the like), pyrophyllite, talc, olivine, magnesium oxide, calcium carbonate, calcium oxide, strontium oxide, barium oxide, textilite and similar glued paper composites, merylinite clay, bentonite clay, sodium silicate, and hexagonal boron nitride. At least one gasket 32 may be an electrically-conductive gasket, or include an electrically-conductive element 130 within an insulating gasket. The electrically conducting gasket or electrically conducting element 130 may comprise at least one of molybdenum, graphite, tungsten, tantalum, niobium, copper, copper alloy, nickel, nickel alloy, iron, and iron alloy. End flanges 34 are attached to one another or to the die assembly by fastening means 38. Such fastening means 38 include, but are not limited to, bolts, threaded rods, or similar fasteners. Tightening of fastening means 38 causes end 34 flanges to exert a compressive load on the die assembly. When the self-pressurizing capsule 12 is at low temperature and has a low internal pressure, the load of the end flanges 34 is supported almost entirely by the die 104 itself. As the self-pressurizing capsule 12 is heated, the internal pressure builds up inside the self-pressurizing capsule 12, causing its walls to deform outward against the pressure transmission medium 14. As the pressure in the pressure transmission medium 14 builds up, an increasing fraction of the load from the end flanges 34 counterbalances or compensates for the internal pressure within the self-pressurizing capsule 12, and a decreasing fraction of the load force is supported by the die 104.

The pressure vessel 10 may be used to form single crystals of materials such as, but not limited to, metal nitrides, including aluminum nitride, other nitride materials, and the like. To form such single crystals, at least one source material and a solvent that becomes a supercritical fluid under HPHT conditions are sealed within the self-pressurizing capsule 12. Self-pressurizing capsule 12 is then provided to the pressure vessel tooling 10 and subjected to HPHT conditions, under which the solvent becomes a supercritical fluid. The supercritical fluid then reacts with the at least one material to form single crystals.

The following example serves to illustrate the features and advantages offered by the present invention, and is not intended to limit the invention thereto.

### EXAMPLE 1

Pressure vessel tooling for use in a 1000-ton hydraulic press was fabricated as follows. A cemented tungsten carbide die having an inner diameter of about 2.0 inches, an outer diameter of 6.9 inches, and a height of 3.7 inches was shrink-fitted into a steel die sleeve. The die sleeve contained eight axial cooling channels to provide for water cooling of the die. The die and die sleeve were pressed into a belt comprising three compression-fit steel rings having outer diameters of about 10.7 inches, 14.7 inches, and 19 inches, respectively. The die, die sleeve, and steel compression rings had interferences so as to provide compression of the die. The belt assembly was then press-fitted into a fourth steel “guard” ring with an outer lip to permit lifting and transport. Brass rings with channels machined into the inner faces were attached to the top and bottom of the die sleeve, with the channels aligned with the axial cooling channels in the die sleeve so that water could be forced to flow through the channels in a serpentine fashion to provide cooling. Copper tubing was brazed to the upper brass ring in order to provide water flow into and out of the die sleeve. The anvil faces comprised cemented tungsten carbide disks, about 3.8 inches in diameter and about 1.0 inch thick, and were press fitted into steel sleeves and a steel holder. The diameter of the anvil holder was about 5.38 inches at the plane of the anvil face.

About 0.20 g of AlN powder and 0.10 g of NH4F powder were pressed into two pills and placed in a capsule. One pill was placed in the bottom of the capsule, and a baffle was then inserted in the capsule to divide the interior of the capsule into two chambers. The second pill was then placed on top of the baffle such that the two pills were separated by the baffle. The capsule comprised copper with a gold coating approximately 25 microns thick on the inner diameter, and had an outer diameter of about 0.5 inches and a height of about 1.3 inches. About 0.91 g of ammonia was added to the capsule. The capsule was then sealed by pressing a gold-coated copper plug into the open end of the capsule.

The sealed capsule was then placed in an apparatus similar to that shown in FIG. 1. The sealed capsule was inserted into a cell within the die. NaCl pressure transmission medium; a 3-layer foil heater tube, comprising graphite foil, Mo foil, and Ta foil; dual type K thermocouples; steel end caps; and gasketing were also positioned within the die. Two pairs of thermocouple wires, enclosed in an alumina tube, passed through a hole in the center of the bottom anvil and through a hole in the bottom steel end cap. The bare wires then passed through small-bore holes in the NaCl pressure transmission medium. One thermocouple junction, or bead, was positioned at the bottom of the copper capsule and a second thermocouple junction was positioned along the outer capsule diameter near the top of the capsule. The bottom end cap was fabricated from mild steel and the upper end cap was fabricated from stainless steel. The lower outer diameter of the upper end cap had a 45° bevel and was fitted with a brass ring for an improved seal against the die wall. The outer diameter of the lower end cap was separated from the die wall by a pyrophyllite sleeve. A copper gasket separating the top anvil from the top plane of the die and the top end cap provided electrical contact and distribution of the load. The bottom end cap was in direct contact with the lower anvil. A Mylar gasket separated the bottom of the die from the bottom anvil. The heater tube was separated from the die wall by a salt bushing. Graphite powder was blended with NaCl, isopressed, and machined in order to fabricate the bushing. In order to reduce friction during removal of the cell at the conclusion of the run, the outer diameter of the black salt bushing was separated from the die wall by a 0.002 inch thick Pb foil.

The capsule was heated to a temperature of approximately 800° C. by passing current through the heater tube. The capsule was held at temperature for about 16 hours and then cooled. The cell was then pressed out of the die and the pressure transmission medium was dissolved in water. In order to reduce the vapor pressure of ammonia, the capsule was chilled in a dry ice/acetone bath and then punctured with an awl. Upon warming, the ammonia escaped from the capsule. The resulting weight loss due to the escape of ammonia was about 0.87 g, which corresponded to the weight of ammonia still present in the capsule at the end of the run. The near equality of the weights of ammonia before and after the run indicates that the capsule did not burst or leak significantly during the run, thus enabling the AlN powder to be processed in supercritical ammonia in the presence of dissolved NH4F at a temperature of 800° C. Based on the phase diagram of supercritical ammonia, at a temperature of 800° C. and the fraction (70%) of free volume in the capsule filled by ammonia, the pressure generated within the capsule at 800° C., assuming Born-Haber equilibrium but neglecting the effect of dissolved solutes, was about 10 kbar.

While typical embodiments have been set forth for the purpose of illustration, the foregoing description should not be deemed to be a limitation on the scope of the invention. For example, the pressure vessel disclosed herein may be used to form single crystals of materials other than aluminum nitride. Accordingly, various modifications, adaptations, and alternatives may occur to one skilled in the art departing from the spirit and scope of the present invention.

1. A pressure vessel for processing at least one material in a supercritical fluid, the pressure vessel comprising:
a)a capsule for containing said at least one material and said supercritical fluid in a substantially air-free environment, said capsule being self-pressurizing;
b)a pressure transmission medium for maintaining an outer pressure on said capsule, said pressure transmission medium surrounding said capsule;
c)a heating system for heating said capsule, said heating system comprising at least one heating element insertable in said pressure transmission medium such that said at least one heating element is proximate to said capsule and a wattage control system electrically coupled to said at least one heating element, wherein said wattage control system provides power to said at least one heating element;
d)a restraint to contain and hold in place said capsule, said pressure transmission medium, and said at least one heating element, wherein said restraint maintains said capsule, said pressure transmission medium, and said at least one heating element at a constant pressure; and
e)at least one seal for preventing escape of said pressure transmission medium, said at least one seal being disposed between said restraint and said pressure transmission medium.

2. The pressure vessel of claim 1, wherein said heating system further comprises at least one temperature sensor disposed proximate to said capsule for measuring a temperature of said capsule.

3. The pressure vessel of claim 2, wherein said at least one temperature sensor comprises at least one of a thermocouple, a thermistor, and an optical fiber coupled to an optical pyrometer.

4. The pressure vessel of claim 2, wherein said wattage control system provides closed loop temperature control in response to at least one signal generated by said at least one temperature sensor.

5. The pressure vessel of claim 1, wherein said at least one heating element is an electrically resistant heating element comprising at least one of at least one foil, at least one tube, at least one ribbon, at least one bar, and at least one wire, and combinations thereof.

6. The pressure vessel of claim 1, wherein said at least one heating element comprises at least one of graphite, nichrome, niobium, titanium, tantalum, stainless steel, nickel, chromium, zirconium, molybdenum, tungsten, rhenium, hafnium, platinum, silicon carbide, and combinations thereof.

7. The pressure vessel of claim 1, wherein said heating system differentially heats a first portion of said capsule to a first temperature and a second portion of said capsule to a second temperature.

8. The pressure vessel of claim 1, further including a clamp for loading at least one portion of said restraint and reducing at least one of a longitudinal stress and an axial stress on at least one portion of said restraint.

9. The pressure vessel of claim 8, further including at least one gasket disposed between said clamp and at least one portion of said restraint.

10. The pressure vessel of claim 9, wherein said at least one gasket includes an electrically insulating gasket, wherein said electrically insulating gasket is formed from at least one of natural rubber, synthetic rubber, polyester film, polyimide, fluorocarbon polymer, tetrafluoroethylene fluorocarbons, fluorinated ethylene-propylene, pyrophyllite, talc, olivine, magnesium oxide, calcium carbonate, calcium oxide, strontium oxide, barium oxide, textilite, a glued paper composite, merylinite clay, bentonite clay, sodium silicate, and hexagonal boron nitride.

11. The pressure vessel of claim 10, wherein said at least one gasket includes an electrically conductive element within said electrically insulating gasket, wherein said electrically conductive element is formed from at least one of molybdenum, graphite, tungsten, tantalum, niobium, nickel, nickel alloy, iron, iron alloy, and combinations thereof.

12. The pressure vessel of claim 9, wherein said at least one gasket includes an electrically conductive gasket, wherein said electrically conductive gasket is formed from at least one of copper, brass, molybdenum, graphite, nickel, cobalt, iron, and stainless steel.

13. The pressure vessel of claim 1, wherein said at least one seal comprises a top seal and a bottom seal.

14. The pressure vessel of claim 13, wherein said top seal comprises a top end cap and said bottom seal comprises a bottom end cap, and wherein said top end cap and said bottom end cap are formed from steel.

15. The pressure vessel of claim 14, wherein said top end cap further includes a deformable ring to provide a seal between said clamp and said restraint.

16. The pressure vessel of claim 1, wherein said pressure transmission medium is thermally stable up to about 1000° C. and has an internal friction of less than about 0.2.

17. The pressure vessel of claim 16, wherein said pressure transmission medium is a solid up to about 1300° C.

18. The pressure vessel of claim 16, wherein said pressure transmission medium comprises at least one of an alkali metal halide, talc, pyrophyllite, molybdenum disulfide, graphite, hexagonal boron nitride, silver chloride, calcium fluoride, strontium fluoride, calcium carbonate, magnesium oxide, zirconium oxide, merylinite clay, bentonite clay, and sodium silicate.

19. The pressure vessel of claim 18, wherein said pressure transmission medium comprises at least one of sodium chloride, sodium bromide, and sodium fluoride.

20. The pressure vessel of claim 1, wherein said restraint comprises at least one die, at least one punch, and a press.

21. The pressure vessel of claim 20, wherein said at least one die is one of a straight-wall die, an angled-wall die, and a concave-wall die.

22. The pressure vessel of claim 20, wherein said at least one die is formed from one of cemented tungsten carbide and hardened steel.

23. The pressure vessel of claim 20, wherein said at least one die is contained within at least one steel compression ring.

24. The pressure vessel of claim 20, further including a cooling sleeve disposed between said at least one die and said at least one compression ring, wherein said cooling sleeve includes at least one cooling channel for circulating a cooling medium therethrough.

25. The pressure vessel of claim 20, wherein said at least one die is contained within at least one of at least one tension-wound steel wire and at least one steel ribbon.

26. The pressure vessel of claim 20, wherein at least one of said at least one punch is a flat-bottomed punch, and wherein said flat-bottomed punch is squeezed against said at least one die by said press.

27. The pressure vessel of claim 20, wherein said pressure vessel has a pressure response of less than about 0.2.

28. The pressure vessel of claim 27, wherein said pressure response is less than about 0.05.

29. The pressure vessel of claim 1, wherein said restraint comprises a multi-anvil press.

30. The pressure vessel of claim 29, wherein said multi-anvil press comprises at least four anvils.

31. The pressure vessel of claim 29, wherein said multi-anvil press comprises at least four pistons.

32. The pressure vessel of claim 30, further comprising a plurality of support plates, wherein each of said plurality of support plates is disposed between of said at least four anvils and said pressure transmission medium.

33. The pressure vessel of claim 29, wherein said multi-anvil press has a pressure response of less than about 0.2.

34. The pressure vessel of claim 33, wherein said pressure response is less than about 0.05.

35. The pressure vessel of claim 1, wherein said restraint comprises at least two end flanges, a die disposed between said at least two end flanges, and at least one fastener joining said at least two end flanges.

36. The pressure vessel of claim 35, wherein each of said at least two end flanges further includes a structural support for reinforcing each of said at least two end flanges.

37. The pressure vessel of claim 35, wherein said structural support comprises an I-beam.

38. The pressure vessel of claim 35, wherein said at least one fastener comprises at least one of a bolt and a threaded rod.

39. The pressure vessel of claim 1, wherein said capsule is self-pressurizable from about 1 bar up to about 80 kbar.

40. The pressure vessel of claim 39, wherein said capsule is self-pressurizable up to between about 5 kbar and about 80 kbar.

41. The pressure vessel of claim 39, wherein said capsule is self-pressurizable up to between about 5 kbar and about 60 kbar.

42. A capsule for containing at least one material and a supercritical fluid in a substantially air-free environment, wherein said capsule has at least one wall, a closed end, and a sealed end defining a chamber therein for containing said at least one material and said supercritical fluid, and wherein said capsule is self-pressurizing.

43. The capsule of claim 42, wherein said capsule is formed from a malleable metal, and wherein said capsule has a low hydrogen permeability.

44. The capsule of claim 42, wherein said capsule is formed from a first material comprising at least one of stainless steel, copper, silver, gold, and platinum.

45. The capsule of claim 42, wherein said capsule includes an inert liner inserted into said chamber, wherein said inert liner is formed from a second material comprising at least one of gold, platinum, rhodium, palladium, silver, iridium, ruthenium, silica, and wherein said inert liner is between about 1 micron and about 5 mm thick, and wherein said second material is different from said first material.

46. The capsule of claim 42, wherein said at least one wall, said closed end, and said sealed end each have a thickness of between about 0.5 mm and about 25 mm.

47. The capsule of claim 42, wherein said capsule is self-pressurizable from about 1 bar up to about 80 kbar.

48. The capsule of claim 47, wherein said capsule is self-pressurizable up to between about 5 kbar and about 80 kbar.

49. The capsule of claim 47, wherein said capsule is self-pressurizable up to between about 5 kbar and about 60 kbar.

50. A pressure vessel for processing at least one material in an a supercritical fluid, the pressure vessel comprising:
a)a capsule for containing said at least one material and said supercritical fluid in a substantially air-free environment, wherein said capsule has at least one wall, a closed end, and a sealed end defining a chamber therein for containing said at least one material and said supercritical fluid, and wherein said capsule is self-pressurizing;
b)a pressure transmission medium for maintaining an outer pressure on said capsule, said pressure transmission medium surrounding said capsule;
c)a heating system for heating said capsule, said heating system comprising at least one heating element insertable in said pressure transmission medium such that said at least one heating element is proximate to said capsule, at least one temperature sensor disposed proximate to said capsule for measuring a temperature of said capsule, and a wattage control system electrically connected to said at least one heating element and said at least one temperature sensor, wherein said wattage control system provides power to said at least one heating element and controls said temperature;
d)a restraint to contain and hold in place said capsule, said pressure transmission medium, and said at least one heating element, wherein said restraint maintains said capsule, said pressure transmission medium, and said at least one heating element at a constant pressure; and
e)at least one seal for preventing escape of said pressure transmission medium, said at least one seal being disposed between said restraint and said pressure transmission medium.

51. The pressure vessel of claim 50, wherein said at least one heating element is an electrically resistant heating element comprising one of at least one foil, at least one tube, at least one ribbon, at least one bar, and at least one wire, and combinations thereof.

52. The pressure vessel of claim 50, wherein said at least one heating element comprises one of graphite, nichrome, niobium, titanium, tantalum, stainless steel, nickel, chromium, zirconium, molybdenum, tungsten, rhenium, hafnium, platinum, silicon carbide, and combinations thereof.

53. The pressure vessel of claim 50, wherein said at least one temperature sensor comprises at least one of a thermocouple, a thermistor, and an optical fiber coupled to an optical pyrometer.

54. The pressure vessel of claim 50, wherein said wattage control system provides closed loop temperature control in response to at least one signal generated by said at least one temperature sensor.

55. The pressure vessel of claim 50, wherein said heating system differentially heats a first portion of said capsule to a first temperature and a second portion of said capsule to a second temperature.

56. The pressure vessel of claim 50, further including a clamp for loading said restraint and reducing at least one of a longitudinal stress and an axial stress on at least one portion of said restraint.

57. The pressure vessel of claim 56, further including at least one gasket disposed between said clamp and at least one portion of said restraint.

58. The pressure vessel of claim 57, wherein said at least one gasket includes an electrically insulating gasket, wherein said electrically insulating gasket is formed from at least one of natural rubber, synthetic rubber, polyester film, polyimide, fluorocarbon polymer, tetrafluoroethylene fluorocarbons, fluorinated ethylene-propylene, pyrophyllite, talc, olivine, magnesium oxide, calcium carbonate, calcium oxide, strontium oxide, barium oxide, textilite, a glued paper composite, merylinite clay, bentonite clay, sodium silicate, and hexagonal boron nitride.

59. The pressure vessel of claim 58, wherein said at least one gasket includes an electrically conductive element within said electrically insulating gasket, wherein said electrically conductive element is formed from at least one of molybdenum, graphite, tungsten, tantalum, niobium, nickel, nickel alloy, iron, iron alloy, and combinations thereof.

60. The pressure vessel of claim 59, wherein said at least one gasket includes an electrically conductive gasket, wherein said electrically conductive gasket is formed from at least one of copper, brass, nickel, cobalt, iron, and stainless steel.

61. The pressure vessel of claim 50, wherein said at least one seal comprises a top seal and a bottom seal.

62. The pressure vessel of claim 61, wherein said top seal comprises a top end cap and said bottom seal comprises a bottom end cap, and wherein said top end cap and said bottom end cap are formed from steel.

63. The pressure vessel of claim 62, wherein said top end cap further includes a deformable ring to provide a seal between said clamp and said restraint.

64. The pressure vessel of claim 50, wherein said pressure transmission medium is thermally stable up to about 1000° C. and has an internal friction of less than about 0.2.

65. The pressure vessel of claim 64, wherein said pressure transmission medium is a solid up to about 1300° C.

66. The pressure vessel of claim 64, wherein said pressure transmission medium comprises at least one of an alkali metal halide, talc, pyrophyllite, molybdenum disulfide, graphite, hexagonal boron nitride, silver chloride, calcium fluoride, strontium fluoride, calcium carbonate, magnesium oxide, zirconium oxide, merylinite clay, bentonite clay, and sodium silicate.

67. The pressure vessel of claim 66, wherein said pressure transmission medium comprises at least one of sodium chloride, sodium bromide, and sodium fluoride.

68. The pressure vessel of claim 50, wherein said restraint comprises at least one die, at least one punch, and a press.

69. The pressure vessel of claim 68, wherein said at least one die is one of a straight-wall die, an angled-wall die, and a concave-wall die.

70. The pressure vessel of claim 68, wherein said at least one die is formed from one of cemented tungsten carbide and hardened steel.

71. The pressure vessel of claim 70, wherein said at least one die is contained within at least one steel compression ring.

72. The pressure vessel of claim 70, further including a cooling sleeve disposed between said at least one die and said at least one compression ring, wherein said cooling sleeve includes at least one cooling channel for circulating a cooling medium therethrough.

73. The pressure vessel of claim 70, wherein said at least one die is contained within at least one of at least one tension-wound steel wire and at least one steel ribbon.

74. The pressure vessel of claim 68, wherein at least one of said at least one punch is a flat-bottomed punch, and wherein said flat-bottomed punch is squeezed against said at least one die by said press.

75. The pressure vessel of claim 74, wherein said pressure vessel has a pressure response of less than about 0.2.

76. The pressure vessel of claim 75, wherein said pressure response is less than about 0.05.

77. The pressure vessel of claim 50, wherein said restraint comprises a multi-anvil press.

78. The pressure vessel of claim 77, wherein said multi-anvil press comprises at least four anvils.

79. The pressure vessel of claim 77, wherein said multi-anvil press comprises at least four pistons.

80. The pressure vessel of claim 78, further comprising a plurality of support plates, wherein each of said plurality of support plates is disposed between of said at least four anvils and said pressure transmission medium.

81. The pressure vessel of claim 77, wherein said multi-anvil press has a pressure response of less than about 0.2.

82. The pressure vessel of claim 81, wherein said pressure response is less than about 0.05.

83. The pressure vessel of claim 50, wherein said restraint comprises at least two end flanges, a die disposed between said at least two end flanges, and at least one fastener joining said at least two end flanges.

84. The pressure vessel of claim 83, wherein each of said at least two end flanges further includes a structural support for reinforcing each of said at least two end flanges.

85. The pressure vessel of claim 83, wherein said structural support comprises an I-beam.

86. The pressure vessel of claim 83, wherein said at least one fastener comprises at least one of a bolt and a threaded rod.

87. The pressure vessel of claim 50, wherein said capsule is formed from a malleable metal, and wherein said capsule has a low hydrogen permeability.

88. The pressure vessel of claim 50, wherein said capsule is formed from a first material comprising at least one of stainless steel, copper, silver, gold, and platinum.

89. The pressure vessel of claim 50, wherein said capsule further includes an inert liner inserted into said chamber, wherein said inert liner is formed from a second material comprising at least one of gold, platinum, rhodium, palladium, silver, iridium, ruthenium, silica, and wherein said inert liner is between about 1 micron and about 5 mm thick, and wherein said second material is different from first material.

90. The pressure vessel of claim 50, wherein said at least one wall, said closed end, and said sealed end each have a thickness of between about 0.5 mm and about 25 mm.

91. The pressure vessel of claim 50, wherein said capsule is self-pressurizable from about 1 bar up to about 80 kbar.

92. The pressure vessel of claim 91, wherein said capsule is self-pressurizable up to between about 5 kbar and about 80 kbar.

93. The pressure vessel of claim 91, wherein said capsule is self-pressurizable up to between about 5 kbar and about 60 kbar.

94. A method of using a pressure vessel to process at least one material at high temperature and high pressure in the presence of a supercritical fluid, the method comprising the steps of:
a)providing a sealed capsule containing the at least one material and a solvent that forms a supercritical fluid, wherein the capsule is self-pressurizing;
b)providing a pressure vessel comprising a restraint for containing the sealed capsule, a pressure transmission medium disposed within the pressure vessel, and at least one heating element disposed within the pressure transmission medium and electrically coupled to a wattage control system;
c)disposing the sealed capsule within the pressure transmission medium such that the sealed capsule is proximate to the at least one heating element;
d)placing the pressure vessel containing the pressure transmission medium, the sealed capsule, and the at least one heating element in a press;
e)pressurizing the press to apply a predetermined pressure to the pressure vessel, the pressure transmission medium, the sealed capsule, and the at least one heating element;
f)providing electrical power from the wattage control system to the at least one heating element, thereby heating the sealed capsule to a predetermined temperature, wherein the solvent contained within the sealed capsule becomes a supercritical fluid and wherein the supercritical fluid generates a predetermined pressure within the sealed capsule; and
g)counterbalancing the predetermined pressure within the sealed capsule by maintaining an equivalent pressure with the restraint and transmitting the equivalent pressure through the pressure transmission medium, wherein the at least one material is processed at high temperature and high pressure in the presence of a supercritical fluid.

95. The method of claim 94, wherein the restraint comprises at least one die, at least one punch, and a hydraulic press, and wherein the pressure transmission medium and the heating element are disposed within the die; and wherein the step of disposing the sealed capsule within the pressure vessel comprises disposing the sealed capsule within the die such that the sealed capsule is proximate to the at least one heating element.

96. The method of claim 95, wherein the restraint comprises a die, a top punch, and a bottom punch, wherein the top punch and the bottom punch oppose each other, and wherein the step of pressurizing the press to apply a predetermined pressure to the pressure vessel comprises pressurizing the press to apply a predetermined pressure onto the top punch and the bottom punch.

97. The method of claim 96, wherein the step of pressurizing the press to apply a predetermined pressure to the pressure vessel comprises the steps of:
a)pressurizing the press to apply a first predetermined pressure onto the top punch and the bottom punch; and
b)adjusting the predetermined pressure to maintain the top and bottom punches at one of a fixed position and a stroke as the capsule is heated and pressure builds up therein.

98. The method of claim 96, further including the step of inserting at least one temperature sensor within the pressure vessel such that the temperature sensor is disposed proximate to the sealed capsule, wherein the at least one temperature sensor is electrically coupled to the wattage control system.

99. The method of claim 98, wherein the step of providing electrical power from the wattage control system to the at least one heating element further comprises providing closed loop temperature control in response to at least one signal generated by the at least one temperature sensor.

100. The method of claim 99, wherein the step of providing closed loop temperature control in response to at least one signal generated by the at least one temperature sensor comprises:
a)providing closed loop temperature control in response to a first signal generated by a first temperature sensor disposed proximate to a first portion of the sealed capsule; and
b)providing closed loop temperature control in response to a second signal generated by second temperature sensor disposed proximate to a second portion of the sealed capsule.

101. A method of processing at least one material at high temperature and high pressure in the presence of a supercritical fluid, the method comprising the steps of:
a)providing a sealed capsule containing the at least one material and a solvent that forms a supercritical fluid, wherein the capsule is self-pressurizing;
b)providing a pressure vessel comprising a restraint, a pressure transmission medium disposed within the restraint, and at least one heating element disposed within the restraint;
c)disposing the sealed capsule within the pressure transmission medium such that the sealed capsule is proximate to the at least one heating element;
d)heating the sealed capsule to a predetermined temperature by providing electrical power to the at least one heating element, wherein the solvent contained within the sealed capsule becomes a supercritical fluid and wherein the supercritical fluid generates a predetermined pressure within the sealed capsule; and
e)counterbalancing the predetermined pressure within the sealed capsule by applying a pressure to the restraint, wherein the at least one material reacts with the supercritical fluid within the sealed capsule.

102. A metal nitride single crystal, wherein the metal nitride single crystal is formed by: enclosing a metal nitride source material and a solvent within a sealed capsule that is self-pressurizing; disposing the sealed capsule within a pressure vessel comprising a restraint, a pressure transmission medium disposed within the restraint, and at least one heating element disposed within the restraint; heating the sealed capsule to a predetermined temperature, wherein the solvent contained within the sealed capsule becomes a supercritical fluid and generates a predetermined pressure within the sealed capsule; and counterbalancing the predetermined pressure within the sealed capsule by applying a pressure to the restraint; wherein the metal nitride source material reacts with the supercritical fluid within the sealed capsule to form a metal nitride single crystal at high temperature and high pressure.

103. The method of claim 102, wherein said metal nitride comprises aluminum nitride.
